(19) United States
(12) Patent Application Publication
(10) Pub. No.: US 2006/0164801 A1
(43) Pub. Date: Jul. 27, 2006

(54) Display apparatus

(76) Inventor: Ki Bok Yoo, Gumi-city (KR)

Correspondence Address: OSHA LIANG L.L.P., 1221 MCKINNEY STREET, SUITE 2800, HOUSTON, TX, 77010, US

(21) Appl. No.: 11/118,625

(22) Filed: Apr. 29, 2005

(30) Foreign Application Priority Data
Jan. 27, 2005 (KR) P2005-0007551

(51) Int. Cl. H05K 5/00

(52) U.S. Cl. 361/683

(57) ABSTRACT

Display apparatus including a base, a monitor rotatably coupled to the base, and a magnetic type holding device for securing the monitor to the base, thereby holding the monitor, more securely.

### CROSS-REFERENCE TO RELATED APPLICATION

This application claims the benefit of Korean Application No. P2005-0007551 filed on Jan. 27, 2005, which is hereby incorporated by reference as if fully set forth herein.

### BACKGROUND OF THE INVENTION

1. Field of the Invention

The present invention relates to display apparatuses, and more particularly, to a display apparatus which can fix a monitor, securely.

2. Discussion of the Related Art

In general, the display apparatus receives an aerial wave, and reproduces an image, or reproduces an image from an image recording medium, particularly, a DVD (Digital Video Disk), and displays the reproduced image.

The display apparatus is provided with a base, and a monitor coupled to the base, for displaying a reproduced image. The base is provided with a mounting portion for mounting the DVD, and electric components, such as a reproducing device like a DVD player for reproducing an image from the DVD, and so on.

Recently, a display apparatus is under development, which is fixedly secured to a ceiling of a car or the like, and, if the user intends to watch a movie or the like, the monitor is rotated at a predetermined angle with reference to the base, to unfold the monitor.

The monitor is rotated by a rotating device driven by a motor or the like in folding, or unfolding the monitor. After the monitor is folded, the monitor is held with a mechanical holding device, such as a latch, or the like on one side of the base portion.

However, in order to unfold the monitor again, since the user is required to unfold the monitor after releasing the mechanical holding device manually, folding/unfolding of the monitor is not easy.

Moreover, in order to unfold the monitor during a driver drives a car, since the driver is required to stretch an arm toward the ceiling, and release the holding device, before unfolding the monitor, an accident is liable to happen during running of the car.

Furthermore, if the user applies an excessive force to the monitor for folding/unfolding the monitor, the holding device is liable to damage, or a coupling portion between the monitor and the base is liable to break.

### SUMMARY OF THE INVENTION

Accordingly, the present invention is directed to an display apparatus that substantially obviates one or more problems due to limitations and disadvantages of the related art.

An object of the present invention is to provide an display apparatus which can be folded/unfolded, securely.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a display apparatus includes a base, a monitor rotatably coupled to the base, and a magnetic type holding device for securing the monitor to the base.

The magnetic holding device includes a magnet mounted on one of the base and the monitor, and a metal member on the other one opposite to the magnet. The magnetic type holding device further includes a coil wound on the metal member. A current flows to the coil so that a repelling force is generated between the magnet and the metal member for a preset time period when the monitor is being opened.

The base is fixedly secured to a ceiling of a car, and the monitor is rotated, and unfolded downwardly. At least two of the magnetic type holding devices are provided along circumferences of the base and the monitor at regular intervals.

The apparatus further includes a limit switch mounted on either the base or the monitor. The rotating shaft of the monitor is coupled to the motor, for selective rotation. When the other side opposite to the limit switch comes into contact, operation of the motor stops.

The limit switch includes a projection, a spring for elastically supporting a bottom of the projection, and a switch part to be brought into contact with the bottom of the projection, selectively.

The base includes an image recording medium mounting portion visible in night at one side surface for mounting an image recording medium therein. The mounting portion has a fluorescent material coated thereon. The base has a thickness which becomes the thinner as it goes from one side the monitor is rotatably coupled thereto to the other side the farther.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIG. 1 illustrates a plan view of a display apparatus in accordance with a preferred embodiment of the present invention;

FIG. 2 illustrates a side view of a display apparatus in accordance with a preferred embodiment of the present invention;

FIG. 3 illustrates a side sectional view of a display apparatus in accordance with a preferred embodiment of the present invention;

FIG. 4 illustrates a perspective view of a display apparatus in accordance with a preferred embodiment of the present invention;

FIG. 5 illustrates a side view of key parts of a magnetic type holding device in accordance with a preferred embodiment of the present invention;

FIG. 6 illustrates a plan view of key parts of a magnetic type holding device in accordance with a preferred embodiment of the present invention;

FIG. 7 illustrates a diagram showing a monitor rotating structure of a display apparatus in accordance with a preferred embodiment of the present invention, schematically; and

FIG. 8 illustrates a section of a limit switch in accordance with a preferred embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

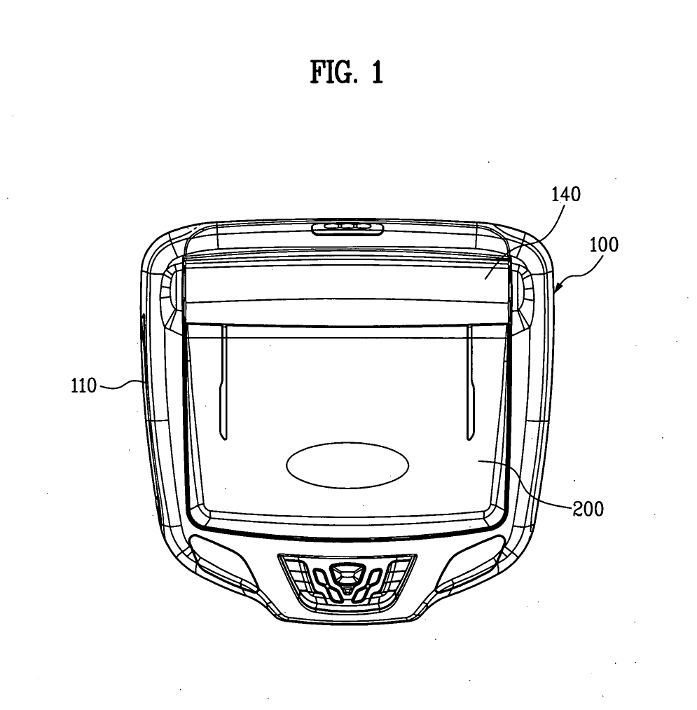

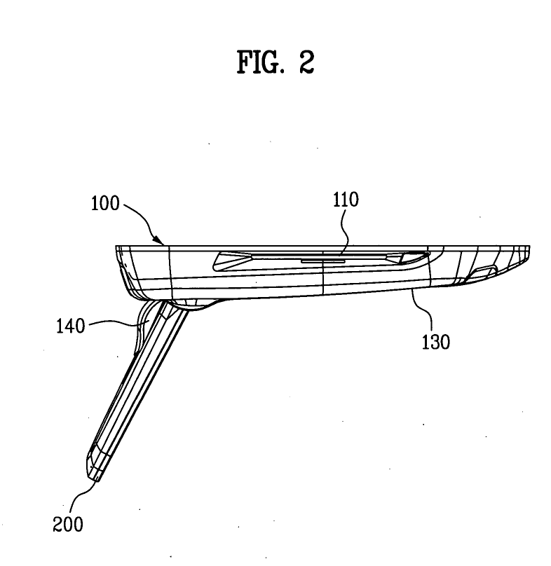

A display apparatus in accordance with a preferred embodiment of the present invention will be described with reference to FIGS. 1 to 8. FIG. 1 illustrates a plan view of a display apparatus in accordance with a preferred embodiment of the present invention, and FIG. 2 illustrates a side view of a display apparatus in accordance with a preferred embodiment of the present invention.

Referring to FIGS. 1 and 2, the display apparatus includes a base 100, and a monitor 200 rotatably coupled to the base 100, for displaying an image.

It is preferable that the base 100 has an image recording medium mounting portion 110 at one side thereof, and inside of the base, there are various electrical components (not shown) including a DVD player and the like for reproducing the image from the image recording medium.

It is preferable that a portion where the image recording medium mounting portion 110 is mounted therein has a color different from other portions. Particularly, it is preferable that a fluorescent material is coated around the mounting portion 110 for recognizing a position of the mounting portion 10 during night.

The base 100 has an upper surface fixedly secured to a ceiling of a car or the like, and a lower surface having a monitor receiving recess 120 formed therein. The monitor receiving recess 120 has a shape in complementary to the monitor 200, and the base 100 has a shape of which thickness becomes the thinner as the shape goes from a rear portion rotatably coupled to the monitor 200 to a front portion. That is, the lower surface 130 of the base having the monitor receiving recess 120 is sloped at a predetermined slope.

In the meantime, the monitor 200 is rotatably coupled to the base 100, such that the monitor 200 is folded/unfolded as the monitor 200 rotates around one edge of the monitor 200, in more detail, a rear edge of the monitor 200.

There is a cover 140 at a rear edge of the base 100 for covering the rear edge of the monitor 200. The cover 140, with a curved shape, has a front edge in close contact with an underside surface of the rear of the monitor 200, and a rear edge elastically supported by a torsion spring (not shown) at the rear edge of the base 100.

In order to make the monitor 200 to rotate, a gap is formed between a rear wall of the monitor receiving recess 120 and the rear edge of the monitor 200, and the cover 140 covers the gap for preventing foreign matters, or a finger of the user from getting therein.

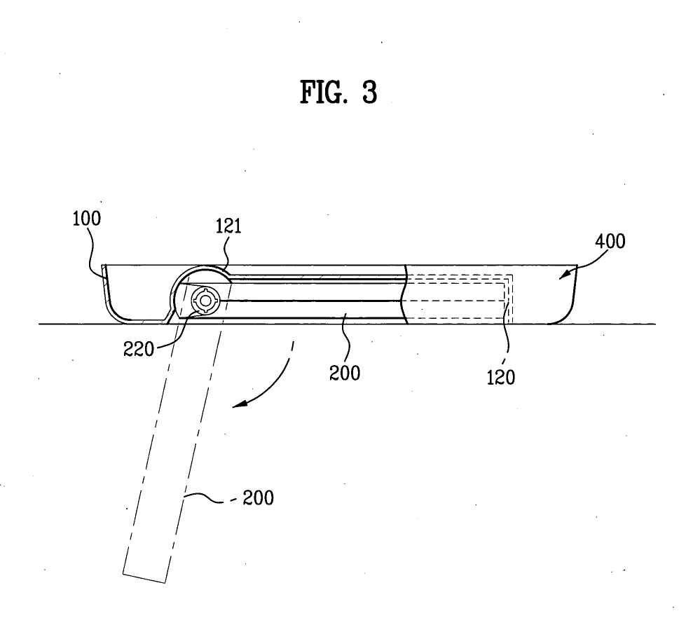

FIG. 3 illustrates a side sectional view of a display apparatus in accordance with a preferred embodiment of the present invention.

Referring to FIG. 3, in order to make the monitor 200 to form an angle more than 90° from the base, a recessed portion 121 is formed along the rear edge of the monitor receiving recess 120.

The recessed portion 421 enables the monitor 200 to rotate without the rear edge of the monitor 200 to interfere with the edge of the monitor receiving recess 120. Moreover, since the monitor 200 can rotate to a greater angle, a field of vision of the driver shielded by the monitor 200 can be minimized.

FIG. 4 illustrates a perspective view of a display apparatus of the present invention.

Referring to FIG. 4, for secure sustenance of a folded state of the monitor 200, a magnetic type holding device is mounted on the base 100 and a portion of the monitor 200 opposite thereto.

It is preferable that the magnetic holding device includes a magnet 510 and a metal member 520. The magnet 510 is mounted on either the base 100 or the monitor 200, and preferably formed of a permanent magnet. The metal member 520 is mounted on the other side opposite to the magnet 510, for holding the monitor 200 in a folded state through joining by magnetic force between the magnet 510 and the metal member 520. Opposite to this, if a downward force greater than the magnetic force between the magnet 510 and the metal member 520 is applied to the monitor, the monitor 200 is rotated, so as to be unfolded.

FIG. 4 illustrates a diagram illustrating an example in which a metal member 520 is mounted at one side of the monitor receiving recess 120 in the base, and the magnet 510 is mounted at one side of the monitor 200. It is preferable that the magnet 510 is mounted at a middle of an inside surface of the monitor 200, and the metal member 520 is mounted at a middle of a front edge of the monitor receiving recess 120.

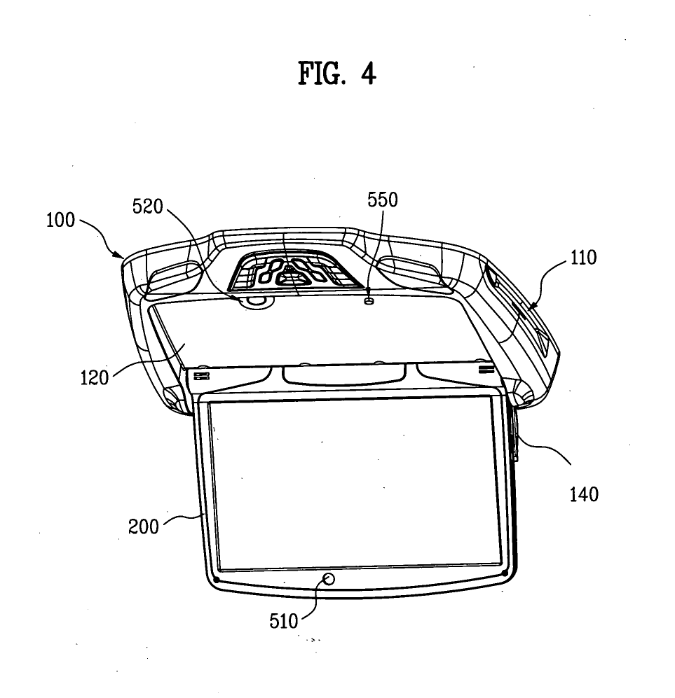

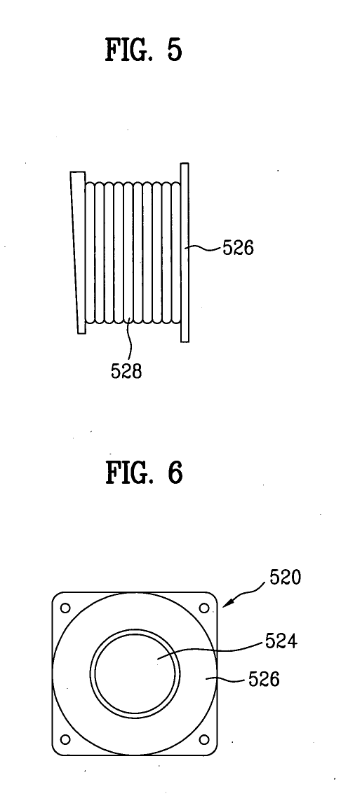

FIG. 5 illustrates a side view of key parts of a magnetic type holding device in accordance with a preferred embodiment of the present invention, and FIG. 6 illustrates a plan view of key parts of a magnetic type holding device in accordance with a preferred embodiment of the present invention.

Referring to FIGS. 5 and 6, the metal member 520 includes a cylindrical steel core 524 at a center portion of the metal member, and a coil wound on an outside circumferential surface of the steel core 524. The coil 528 has enamel, an electric insulating material, coated on an outside of the coil 528, for forming a magnetic field in the vicinity of the metal member 520 when electricity is applied to the coil 528, to make the metal member 520 to function as an electric magnet.

In the meantime, if polarities of the magnet 510 on the monitor 200, and a surface of the metal member 520 opposite thereto are identical, repelling forces which push away each other are generated. By controlling a direction of the current flowing in the metal member 520, the repelling force may be generated between the magnet 510 and the metal member 520.

Therefore, it is preferable that, if it is intended to unfold the monitor 200, the current is made to flow in the coil 528 such that the repelling force is generated between the magnet 510 and the metal member 420.

That is, when the monitor 200 is unfolded, a temporary current is made to flow in the coil 528 so that the repelling force is generated between the magnet 510 and the metal member 520, for preventing a load from applying to a motor that is to rotate the monitor 200 to overcome an attraction force between the magnet 510 and the metal member 520.

It is preferable that a time period for supplying the current to generate the repelling force between the magnet 510 and the metal member 520 is limited to be within a preset time period, for reducing power consumed at the coil 528, and, when the user intends to fold the monitor 200, a state is required, in which the repelling force is removed.

If the preset time period is too short, a folded state is liable to be maintained again by the attraction force between the magnet 510 and the metal member 520 because the repelling force is removed too early. Accordingly, it is preferable that the preset time period is approx. 1 second.

In the meantime, since the base 100 is fixedly secured to the ceiling of the car, if a switch for supplying power to the coil 528 is on the ceiling or the base 100, it is difficult to handle the switch while running. Therefore, it is preferable that the switch for supplying power to the coil selectively is mounted in front of a driver's seat. According to this, even during running, the switch can be handled easily so that persons in the same car in a seat on a side of the driver's seat, and/or in a seat behind the driver's seat can watch an image on the monitor.

Moreover, it is preferable that the switch is operated such that electricity is supplied to the coil 528, as well as a function of operating the motor for opening the monitor 200 are also performed at the same time.

The switch for supplying electricity to the coil 528 may be mounted on a remote controller, for more convenient handling.

In the meantime, it is preferable that electric insulating members 526 are mounted at opposite peripheries of the metal member 520. Accordingly, even if there is a partial electricity leakage from the coil 528 to the metal member 520, transmission of the leaked electricity to the base 100, and giving damage to electric components in the base 100 can be prevented.

In the meantime, at least two of the magnetic type holding device may be provided along circumferences of the base 100 and the monitor 200 at regular intervals. In this case, for synchronizing a timing for supplying power to the coils of the magnetic type holding devices, it is preferable that the coils are connected to the power source in parallel.

Referring to FIG. 4, it is preferable that a limit switch 550 is provided at one side of the base 100 for sensing fold/unfold of the monitor 200. The limit switch 550 may be provided at one side of the monitor 200 instead of the base 100.

In more detail, the limit switch 550 is provided at one side of the monitor receiving recess 120 of the base 100. That is, the limit switch 550 is provided at a position adjacent to the magnetic type holding device. The limit switch 550 senses folding of the monitor 200, for stopping operation of the motor, which will be described, later.

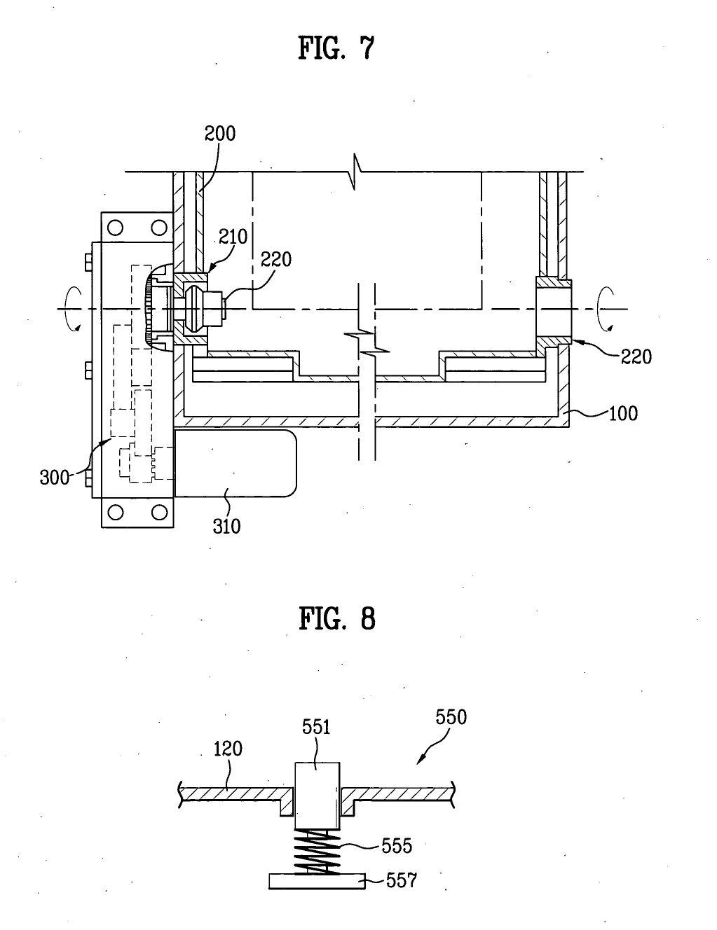

FIG. 7 illustrates a diagram showing a monitor rotating structure of a display apparatus in accordance with a preferred embodiment of the present invention, schematically.

Referring to FIG. 7, though the monitor 200 may be rotated manually, it is preferable that the monitor 200 has a rotating shaft 220 coupled to a motor 310, for selective rotation. Moreover, there is a gear box 300 between the rotating shaft 220 and the motor 310 for increasing to rotate the rotating shaft 220.

Once the monitor is opened as a repelling force is generated between the metal member and the magnet, power is supplied to the motor 310 to generate a rotating force. The rotating force of the motor 310 is transmitted to the rotating shaft 220 of the monitor through the gears in the gear box 300. The monitor 200 is stopped at a predetermined angle by a braking device (not shown) in a state the monitor 200 is rotated to a predetermined angle. The rotating shaft 220 has left and right side supporting portions 210 and 220 at left and right side ends of the rotating shaft 220 for rotatably supporting the rotating shaft 220.

Opposite to this, in folding the monitor 200, the rotating shaft of the motor 310 is rotated in an opposite direction after the braking device is released, to fold the monitor 200. In this instance, the monitor 200 maintains a folded state by attraction between the metal member 520 and the magnet 510.

In this instance, if one side of the monitor 200 comes into contact with the limit switch 550 during the monitor 200 is closed, operation of the monitor 310 stops. For this, the limit switch 550 is electrically connected to the power supply unit which supplies electricity to the motor 310.

FIG. 8 illustrates a section of a limit switch in accordance with a preferred embodiment of the present invention.

Referring to FIG. 8, it is preferable that the limit switch 550 includes a projection 551, a spring 555, and a switch part 557. The monitor receiving portion 120 of the base 100 has a hole at one side for inserting the projection 551 therein, for moving the projection 551 up/down therethrough. It is preferable that there is a guide portion extended downward from a circumference of the hole for guiding movement of the projection 551.

The projection 551 at a bottom is supported with the spring 555. The spring 555 may be constructed of a member formed of rubber or other elastic material.

The switch part 557 is under the projection 551, so that the bottom of the projection 551 is brought into contact with the switch part 557 selectively as the projection 551 moves downward, for change over of contact. By this, a signal is transmitted from the switch part 557 to the motor (310 in FIG. 7), to stop the motor.

Besides above configuration, the limit switch 550 may be a variety of sensing devices which can sense a folded state of the monitor 200.

The foregoing display apparatus can be fabricated in a small size for mounting, not only on the ceiling of a car, but also on a desk or a table, or carrying. Moreover, the display apparatus may be provided with a system which enables to watch a TV or reproduction of a variety of image recording media.

As has been described, the display apparatus of the present invention has the following advantages.

First, the magnetic type holding device provided to the display apparatus can hold the monitor securely in a state the monitor is folded, and, moreover, enables to fold/unfold the monitor more easily, manually, or automatically.

Second, the temporary flow of a current to the coil wound on the metal member generates a repelling force between the magnet and the metal member at the time of unfolding of the monitor, to prevent a load from acting on the motor that rotates the monitor.

Third, the sensing of folding of the monitor with the limit switch, to stop operation of the motor reduces unnecessary power consumption, and prevents a load from acting of the motor.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A display apparatus comprising:
a base;
a monitor rotatably coupled to the base; and
a magnetic type holding device for securing the monitor to the base.

2. The apparatus as claimed in claim 1, wherein the magnetic holding device includes;
a magnet mounted on one of the base and the monitor, and
a metal member on the other one opposite to the magnet.

3. The apparatus as claimed in claim 2, wherein the magnetic type holding device further includes a coil wound on the metal member.

4. The apparatus as claimed in claim 3, wherein a current flows to the coil so that a repelling force is generated between the magnet and the metal member for a preset time period when the monitor is being opened.

5. The apparatus as claimed in claim 3, wherein the base is fixedly secured to a ceiling of a car, and the monitor is rotated, and unfolded downwardly.

6. The apparatus as claimed in claim 1, wherein at least two of the magnetic type holding devices are provided along circumferences of the base and the monitor at regular intervals.

7. The apparatus as claimed in claim 1, further comprising a limit switch mounted on either the base or the monitor.

8. The apparatus as claimed in claim 7, wherein the rotating shaft of the monitor is coupled to the motor, for selective rotation.

9. The apparatus as claimed in claim 8, wherein, when the other side opposite to the limit switch comes into contact, operation of the motor stops.

10. The apparatus as claimed in claim 8, wherein the limit switch includes;
a projection,
a spring for elastically supporting a bottom of the projection, and
a switch part to be brought into contact with the bottom of the projection, selectively.

11. The apparatus as claimed in claim 1, wherein the base includes an image recording medium mounting portion visible in night at one side surface for mounting an image recording medium therein.

12. The apparatus as claimed in claim 11, wherein the mounting portion has a fluorescent material coated thereon.

13. The apparatus as claimed in claim 1, wherein the base has a thickness which becomes the thinner as it goes from one side the monitor is rotatably coupled thereto toward the other side the farther.

14. A display apparatus comprising:
a base;
a monitor rotatably coupled to the base;
a magnetic type holding device including;
a magnet mounted on one of the base and the monitor,
a metal member on the other one opposite to the magnet, and
a coil wound on the metal member; and
a limit switch provided to either the base or the monitor for sensing folding/unfolding of the monitor.
